(19) United States
(12) Patent Application Publication
(10) Pub. No.: US 2013/0175610 A1
(43) Pub. Date: Jul. 11, 2013

(54) TRANSISTOR WITH STRESS ENHANCED CHANNEL AND METHODS FOR FABRICATION

(71) Applicants: Stefan Flachowsky, Dresden (DE); Frank Wirbeleit, Dresden (DE)

(72) Inventors: Stefan Flachowsky, Dresden (DE); Frank Wirbeleit, Dresden (DE)

(73) Assignee: GLOBALFOUNDRIES INC., Grand Cayman (KY)

(21) Appl. No.: 13/347,435

(22) Filed: Jan. 10, 2012

(51) Int. Cl. H01L 29/78; H01L 21/28

(52) U.S. Cl. 257/330; 438/589; 257/E29.262; 257/E21.19

(57) ABSTRACT

A transistor device and methods for its fabrication are provided. In an embodiment, the transistor is fabricated within and on a surface of a semiconductor substrate. The method includes forming a gate structure with a dummy gate electrode material overlying the semiconductor substrate. Recesses are etched into the semiconductor substrate adjacent the gate structure to define a narrow region between the recesses at a selected depth under the surface. The recesses are filled with a stress-inducing material and the dummy gate electrode material is removed to expose the semiconductor substrate. The method further provides for etching the exposed semiconductor substrate to form a recessed gate surface and defining a channel under the recessed gate surface in the narrow region.

### TECHNICAL FIELD

The present disclosure generally relates to transistors and to methods for their fabrication, and more particularly relates to transistors with stress enhanced channels and to method for fabricating transistors with stress enhanced channels.

### BACKGROUND

The majority of present day integrated circuits (ICs) are implemented by using a plurality of interconnected field effect transistors (FETs), which are also called metal oxide semiconductor field effect transistors (MOSFETs), or simply MOS devices or transistors. A MOS device includes a gate electrode as a control electrode and spaced apart source and drain electrodes. Majority charge carriers, electrons or holes, flow from the source electrode to the drain electrode through an active channel under the gate electrode. A control voltage applied to the gate electrode controls the flow of current through the channel between the source and drain electrodes.

The complexity of ICs and the number of devices incorporated in ICs are continually increasing. As the number of devices in an IC increases, the size of individual devices decreases. Device size in an IC is usually noted by the minimum feature size, that is, the minimum line width or the minimum spacing that is allowed by the circuit design rules. As the semiconductor industry moves to smaller minimum feature sizes, the performance of individual devices degrades as the result of scaling. As new generations of integrated circuits and the transistors that are used to implement those integrated circuits are designed, technologists must rely heavily on non-conventional elements to boost device performance.

The performance of a MOS transistor, as measured by its current carrying capability, is proportional to the mobility of the majority carrier in the transistor channel. It is known that applying a longitudinal stress to the channel of a MOS transistor can increase the mobility; a compressive longitudinal stress enhances the mobility of majority carrier holes and a tensile longitudinal stress enhances the mobility of majority carrier electrons. While the use of stress on a channel to improve mobility of the majority carrier is known, improved techniques for applying stress to the channel are desired.

Accordingly, it is desirable to optimize methods for fabricating transistors. In addition, it is desirable to provide an optimized method for fabricating transistors with increased stress on the transistor channel. Furthermore, other desirable features and characteristics will become apparent from the subsequent detailed description and the appended claims, taken in conjunction with the accompanying drawings and the foregoing technical field and background.

### BRIEF SUMMARY

Methods are provided for fabricating a transistor. In accordance with one embodiment, the transistor is fabricated within and on a surface of a semiconductor substrate. The method includes forming a gate structure with a dummy gate electrode material overlying the semiconductor substrate. Recesses are etched into the semiconductor substrate adjacent the gate structure and define a narrow region between the recesses at a selected depth under the surface. The method includes filling the recesses with a stress-inducing material. The method also provides for removing the dummy gate electrode material to expose the semiconductor substrate. The exposed semiconductor substrate is etched to form a recessed gate surface and to define a channel under the recessed gate surface in the narrow region.

In another embodiment, a method is provided for fabricating a transistor within and on a surface of a semiconductor substrate. In the method, recesses are etched into the semiconductor substrate to define a narrow region between the recesses at a selected depth under the surface. The recesses are filled with a stress-inducing material and the semiconductor substrate between the recesses is etched to form a recessed gate surface. In the method, a gate structure is formed on the recessed surface and defines a gate channel under the recessed surface and in the narrow region.

In accordance with another embodiment, a transistor includes a semiconductor substrate having a surface defining a plane. The transistor also includes stress-inducing regions embedded in the semiconductor substrate that define a narrow region between the recesses at a selected depth under the surface. Further, the transistor includes a recessed gate surface formed below the plane. The transistor also includes a gate electrode formed on the recessed gate surface and a channel region at the selected depth and in the narrow region.

### BRIEF DESCRIPTION OF THE DRAWINGS

Embodiments of the transistor and methods of fabrication will hereinafter be described in conjunction with the following drawing figures, wherein like numerals denote like elements, and wherein:

FIGS. 1-13 illustrate, in cross section, a transistor and method steps for its fabrication in accordance with various embodiments herein.

### DETAILED DESCRIPTION

The following detailed description is merely exemplary in nature and is not intended to limit the transistor, or the fabrication methods, applications or uses of the transistor. Furthermore, there is no intention to be bound by any expressed or implied theory presented in the preceding technical field, background or brief summary, or in the following detailed description.

It is known that stress can be used to increase the mobility of majority carriers in a transistor by embedding stress-inducing material adjacent the transistor's gate structure. For instance, a compressive stress can be applied to the channel of a PMOS transistor to increase the mobility of majority carrier holes in the transistor, and a longitudinal tensional stress can be applied to the channel of a NMOS transistor to increase the mobility of majority carrier electrons. Herein, it is further contemplated that modifying the position of the transistor channel relative to the embedded stress-inducing material can further enhance the mobility of majority carriers in the transistor.

In accordance with the various embodiments herein, methods for fabricating a MOS transistor device reposition the transistor channel, relative to conventional transistors, to improve transistor performance. FIGS. 1-13 illustrate, in cross section, a CMOS semiconductor device and method steps for fabricating such a CMOS semiconductor device in accordance with various embodiments herein. As described in greater detail below, the fabricated CMOS semiconductor device includes modifications to the position of its gate structure to enhance effects of stress in order to increase mobility of carriers in the channel regions of both N-type and P-type transistor devices. Although the subject matter is described herein in the context of a CMOS semiconductor device, the subject matter is not intended to be limited to CMOS semiconductor devices, and may be utilized with other MOS semiconductor devices which are not CMOS semiconductor devices. Additionally, although the term “MOS device” properly refers to a device having a metal gate electrode and an oxide gate insulator, that term will be used herein to refer to any semiconductor device that includes a conductive gate electrode (whether metal of other conductive material) that is positioned over a gate insulator (whether oxide or other insulator) which, in turn, is positioned over a semiconductor substrate. Various steps in the fabrication of MOS semiconductor devices are well known and so, in the interest of brevity, many conventional steps will only be mentioned briefly herein or will be omitted entirely without providing the well known process details.

Turning now to FIG. 1, in an exemplary embodiment, the process of fabricating a transistor device 100 begins by forming gate structures 110, 112 overlying isolated regions 114, 116 of semiconductor material 118. The isolated regions 114, 116 are preferably formed from a substrate (or wafer) of semiconductor material 118 (e.g., a silicon-on-insulator (SOI) substrate or a bulk silicon substrate). The semiconductor material 118 is preferably a silicon material, wherein the term “silicon material” is used herein to encompass the relatively pure silicon materials typically used in the semiconductor industry as well as silicon admixed with other elements. Alternatively, the semiconductor material 118 can be realized as germanium, gallium arsenide, and the like, or the semiconductor material 118 can include layers of different semiconductor materials. For convenience, but without limitation, the semiconductor material 118 may hereinafter be referred to as a silicon material. The regions 114, 116 are electrically isolated from neighboring regions of the substrate by performing shallow trench isolation (STI) or another isolation process to form an insulating material 120, such as silicon dioxide, in between the regions 114, 116 of the silicon material 118.

Prior to forming gate structures 110, 112, the isolated regions 114, 116 are doped in a conventional manner to achieve a desired dopant profile for the body regions (or well regions) of the subsequently formed transistor structures. For example, an N-type region 116 of semiconductor material 118 may be formed by masking region 114 and implanting N-type ions, such as phosphorous or arsenic ions, into region 116. In this regard, the N-type region 116 functions as an N-well for a PMOS transistor structure subsequently formed on region 116. In a similar manner, the N-type region 116 is masked and a P-well for a subsequently formed NMOS transistor structure is formed in region 114 by implanting P-type ions, such as boron ions, into region 114. For convenience, the N-type (or N-well) region 116 may alternatively be referred to herein as the PMOS transistor region and the P-type (or P-well) region 114 may alternatively be referred to herein as the NMOS transistor region.

After doping the isolated regions 114, 116, the fabrication process continues by forming the gate structures 110, 112 overlying the isolated regions 114, 116 as described above. The gate structures 110, 112 can be created using a conventional gate stack module or any combination of well-known process steps. It should be understood that various numbers, combinations and/or arrangements of materials may be utilized for the gate structure in a practical embodiment, and the subject matter described herein is not limited to any particular number, combination, or arrangement of gate material(s) in the gate structure. As illustrated in FIG. 1, the gate structures 110, 112 preferably include at least one layer of dummy gate electrode material 122. For example, the gate structure 110, 112 may be formed by depositing one or more layers of gate electrode material 122, such as polycrystalline silicon (polysilicon), overlying the surface 124 of the semiconductor substrate 118.

In the illustrated embodiment, the gate structures 110, 112 are formed with gate caps 126 that overlie the gate electrode material 122. As shown, the gate caps 126 may be formed by alternating layers. Specifically, the gate caps 126 may be formed as cap stacks by depositing and patterning a layer 128 onto gate electrode material 122, a layer 130 onto layer 128, and a layer 132 onto layer 130. In an exemplary embodiment, a layer of silicon nitride (Si₃N₄) 128 is conformably deposited overlying the conductive material to a thickness in the range of about 3 nm to about 5 nm by plasma enhanced chemical vapor deposition (PECVD). Further, a layer of silicon oxide (SiO₂) 130 is deposited by low pressure chemical vapor deposition (LPCVD) to a thickness of between about 10 to about 20 nm. Then, a second layer of silicon nitride 132 is conformably deposited overlying the oxide layer 130 to a thickness in the range of about 3 nm to about 5 nm by PECVD. After the layers of the cap stack are formed, portions of the conductive gate electrode material 122 and capping material 128, 130, 132 are then selectively removed using an anisotropic etchant and a corresponding etch mask to define gate structures 110, 112 on the surface 124 of the silicon material 118.

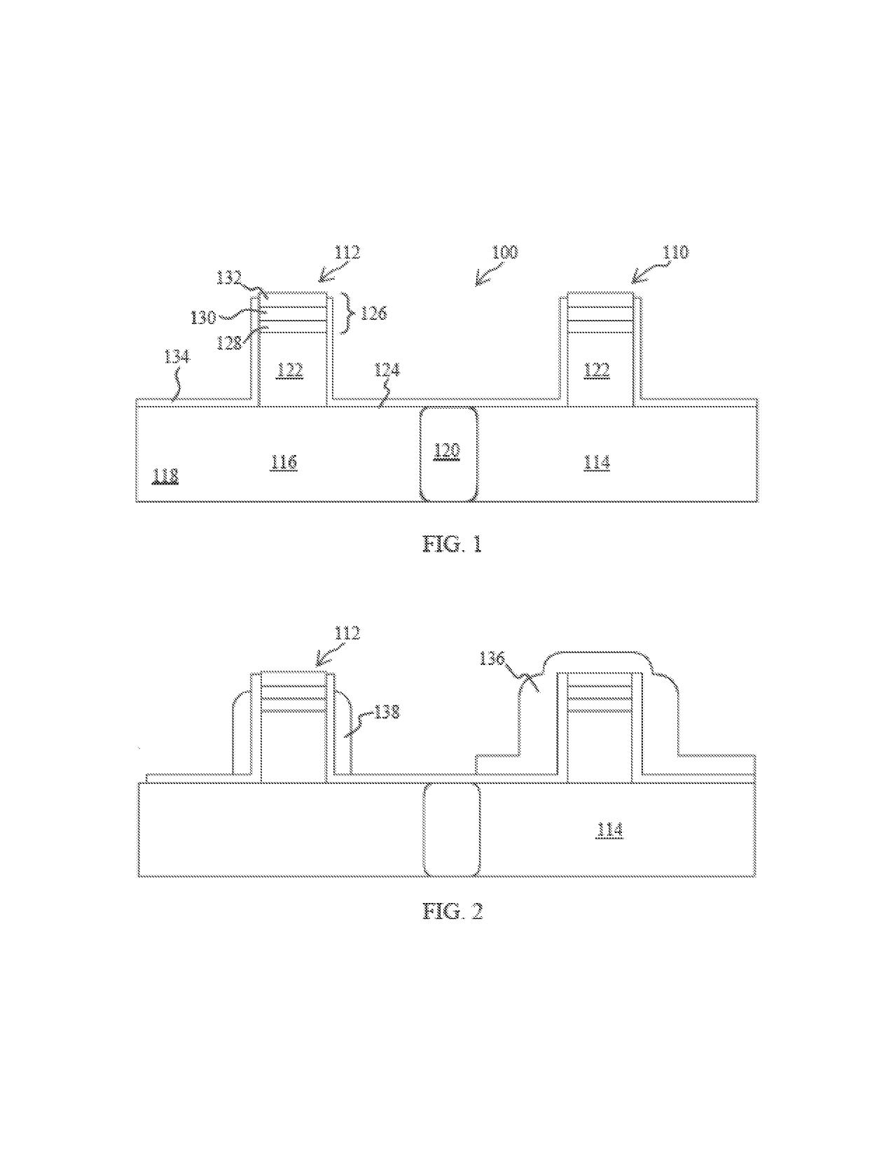

As shown in FIG. 1, a further embodiment includes depositing a liner 134, such as an oxide liner, onto the sidewalls of the gate structures 110, 112, and over isolated regions 114, 116 and insulating material 120. Thereafter, as shown in FIG. 2, a hardmask material, such as silicon nitride, is deposited over the oxide liner 134 and gate caps 126 and then is anisotropically etched to form a hardmask 136 over the isolated region 114 and to form spacers 138 abutting gate structure 112.

In FIG. 3, the exemplary embodiment is shown to include anisotropic etching of the semiconductor substrate 118 in isolated region 116 using the spacers 138 as a mask to form recesses 140. As shown, the recesses 140 are self-aligned with the spacers 138. The etching process may be a dry etch, for instance, reactive ion etching (RIE) using HBr/O₂. The etch results in at least a thin portion of silicon layer 118 left beneath the bottom surface of the recesses 140.

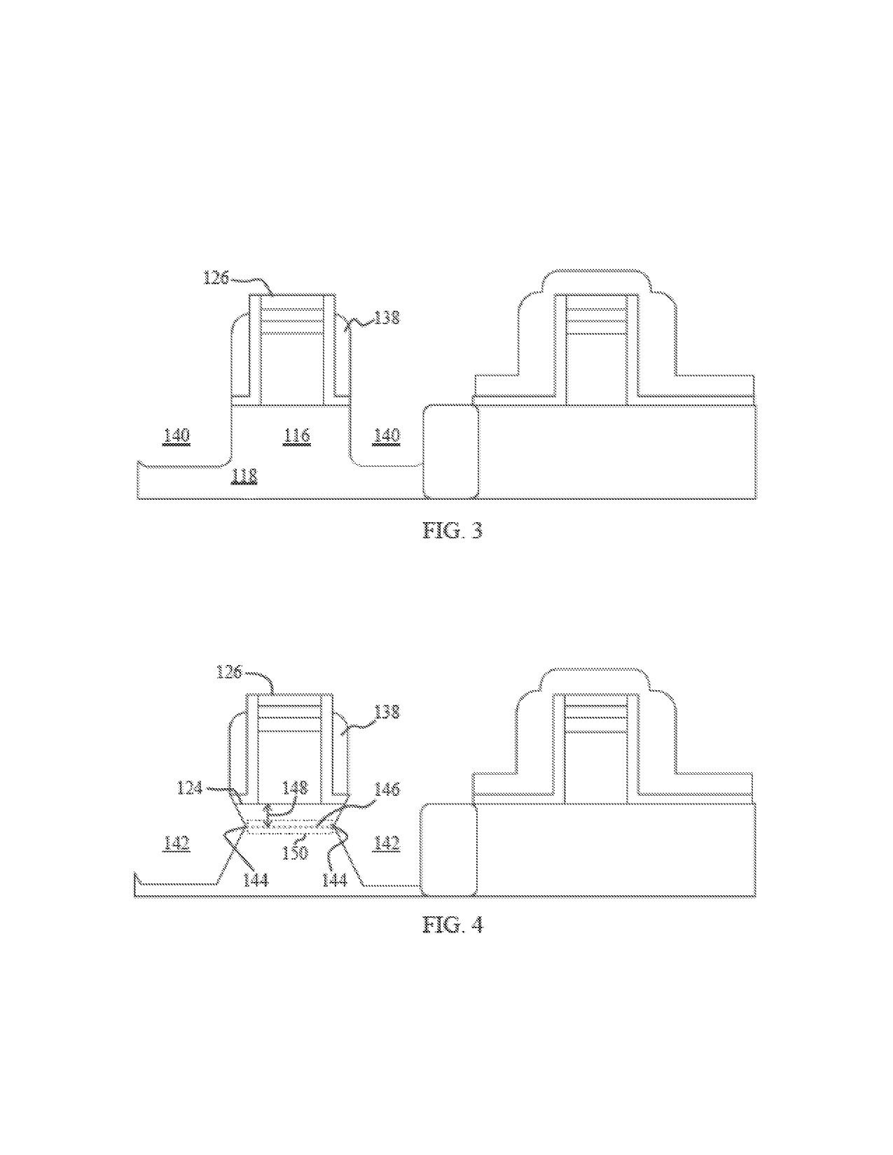

As shown in FIG. 4, further anisotropic etching of the semiconductor substrate 118 is performed to form sigma-shaped recesses 142 in isolated region 116. For example a TMAH (tetramethylammonium hydroxide) wet etch process may be used, with spacers 138 as a mask, to create recesses 142. At least a thin portion of silicon layer 118 is left beneath the bottom surface of the sigma-shaped recesses 142. As shown, the sigma-shaped recesses 142 extend toward one another under the spacers 138 to points 144 that are nearest the other recess 142. A line 146 between the points 144 is defined and is the shortest distance between the recesses 142. The line 146 is positioned at a selected depth below surface 124, preferably about 10 to about 20 nm, as indicated by arrow 148. Further, a narrow region 150 adjacent the line 146 is defined. A time-controlled slow etching process is used and is monitored closely to control the etch depth precisely.

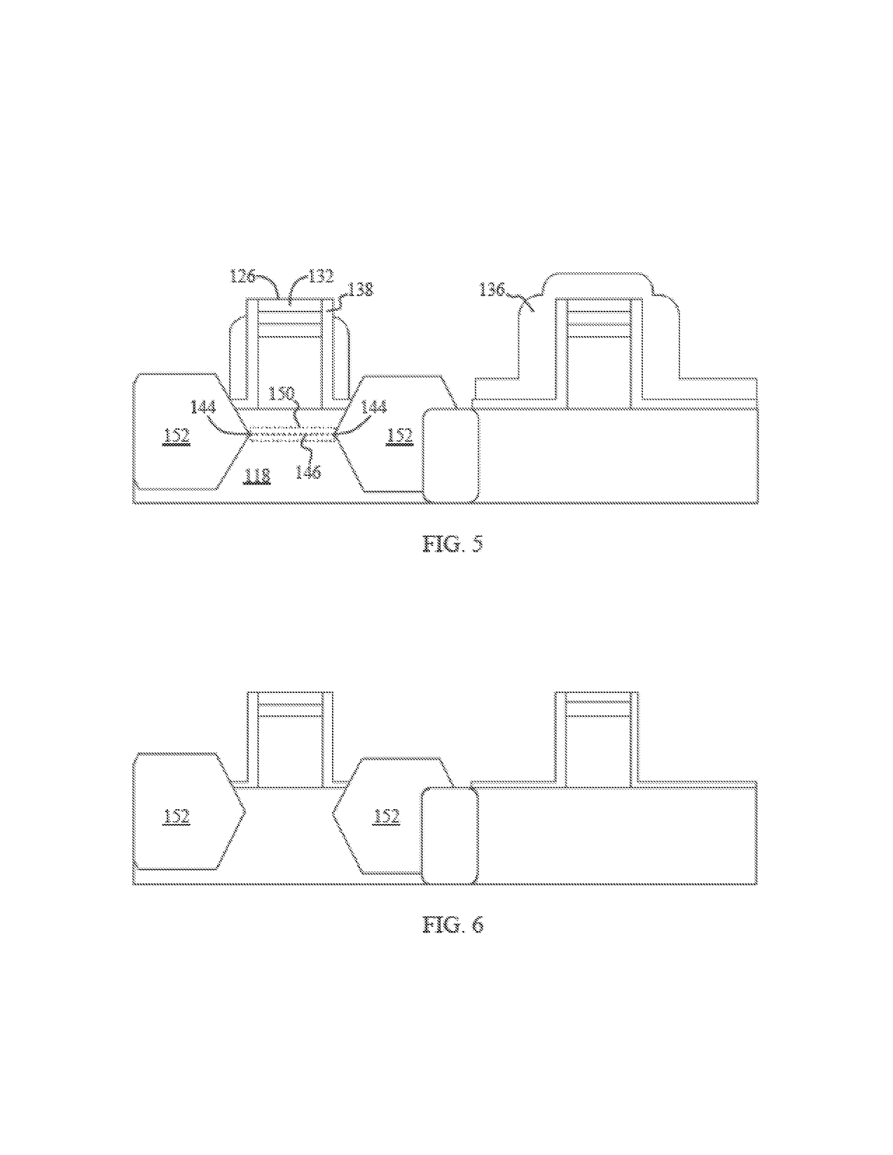

In accordance with a further embodiment herein the structure illustrated in FIG. 5 is achieved by epitaxially growing a stress-inducing material 152, such as SiGe, in the recesses 142. As is known, stress-inducing materials, such as SiGe, include larger substitutional atoms, such as germanium atoms, in their silicon lattice to increase their lattice constant. The local addition of the large substitutional atom to the host silicon lattice creates a compressive stress on the host lattice. As a result, the embedded stress-inducing material 152 increases the compressive stress applied to the silicon layer 118. As identified herein, the applied stress is greatest along line 146 and in the narrow region 150 around line 146 between the points 144. Similarly, if a smaller substitutional atom such as a carbon atom is added to the silicon lattice, the lattice constant decreases, and adding a small substitutional atom to a host silicon lattice creates a tensile stress on the host lattice, which will be applied in a greatest value along line 146 and in the narrow region 150 around line 146 between the points 144.

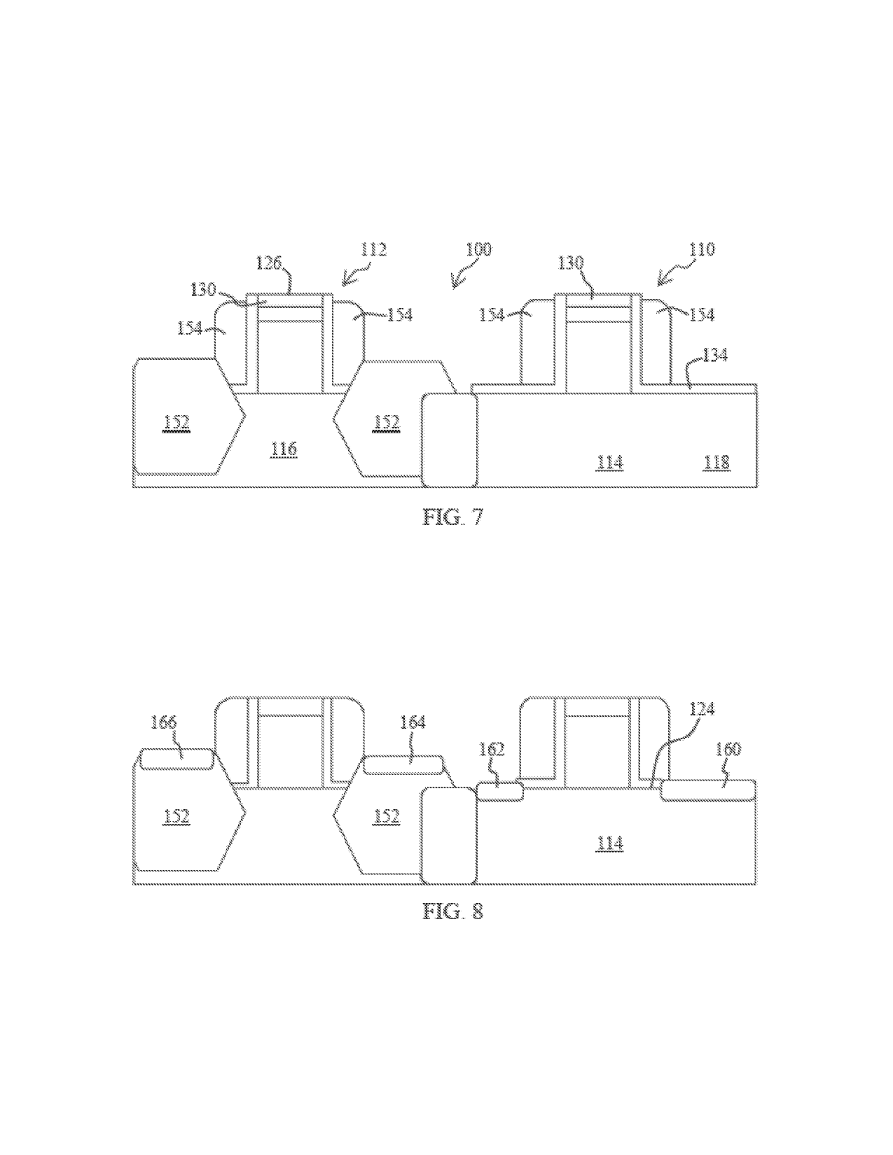

In accordance with a further embodiment herein, nitride material is removed as shown in FIG. 6. Cross-referencing FIGS. 5 and 6, the top layer 132 of the gate cap 126, the spacers 138, and the hard mask 136 are removed using a wet etch. Then, a spacer-forming material is deposited and is anisotropically etched to form spacers 154, as shown in FIG. 7. Thereafter, source and drain implants are performed within the isolated regions 114, 116 of silicon material 118. For example, P-type source and drain extension regions may be formed in the N-well region 116 by masking the NMOS transistor region 114 (e.g., using photoresist or another masking material) and implanting P-type ions, such as boron ions, into the exposed silicon material 118 of the PMOS transistor region 116 to a desired depth and/or sheet resistivity using the gate structure 112 and/or gate cap 126 as an implantation mask. Also, while the NMOS transistor region 114 is masked, N-type halo regions are formed in the channel region underlying the gate structure 112 by implanting N-type ions, such as phosphorous ions or arsenic ions, at an angle to the surface of the silicon material 118 using the gate structure 112 and/or gate cap 126 as an implantation mask.

In accordance with one embodiment, prior to activating the dopant ions of the P-type source/drain extensions and the N-type halo regions, the NMOS transistor region 114 is unmasked while the PMOS transistor region 116 is masked and N-type source/drain extension regions and P-type halo regions are formed in the P-well region 114. In a similar manner as described above, the N-type extension regions are formed by implanting N-type ions, such as phosphorous or arsenic ions, into the exposed silicon material 118 of the NMOS transistor region 114 and the P-type halo regions are formed by implanting P-type ions, such as boron ions, at an angle to the surface of the silicon material 118 using the gate structure 110 and/or gate cap 126 as an implantation mask. In an embodiment, after the N-type source/drain extensions and P-type halo regions are formed in the P-well region 114, the PMOS transistor region 116 is unmasked.

In accordance with one embodiment, after forming the source/drain extensions and halo regions in both transistor regions 114, 116, a diffusionless annealing (or ultrafast annealing (UFA)) is performed for a high degree of dopant activation as well as to re-crystallize the substrate silicon material 118 and remedy any lattice defects that may have been caused by the ion implantation process steps without causing diffusion of the implanted dopant ions. In this regard, the transistor structure 100 is heated (e.g., by performing a flash anneal or a laser anneal) for an amount of time that is less than a threshold amount of time that would otherwise result in the diffusion of the dopant ions in the source/drain extensions and/or halo regions. In an exemplary embodiment, the semiconductor device structure 100 is heated to a temperature of about 1250° C. or more for about 10 milliseconds or less to inhibit diffusion of dopant ions in the source/drain extensions and/or halo regions or otherwise ensure that any diffusion of dopant ions in the source/drain extensions and/or halo regions is negligible. The relatively high temperature of the diffusionless anneal activates the dopant ions of the source/drain extensions and/or halo regions but the duration of the diffusionless anneal is such that any lateral diffusion of the dopant ions is inhibited or otherwise prevented. It should be noted that due to the diffusionless annealing processes described herein, in exemplary embodiments, the source/drain extensions are formed by ion implantation using only the gate structures and/or gate caps as ion implantation masks and without the use of any offset spacer(s) to define the lateral extent of the source/drain extension regions.

Referring now to FIG. 8, in an exemplary embodiment, fabrication of the semiconductor device structure 100 continues by removing the oxide layer 130 from the gate caps 126 and removing the exposed oxide liner 134. Typically, the removal of the oxide layer 130 and oxide liner 134 is performed by an oxide preclean process. Then, fabrication of the semiconductor device structure 100 continues by forming silicide regions 160, 162, 164, 166. In an exemplary embodiment, the silicide regions 160, 162, 164, 166 are formed by depositing a layer of silicide-forming metal onto the surface 124 of isolated region 114 and the surfaces of the SiGe 152. The silicide-forming metal may be realized as, for example, nickel platinum, cobalt, nickel, rhenium, ruthenium, or palladium, or alloys thereof. In an exemplary embodiment, the silicide-forming metal is deposited (e.g., by sputtering) to a thickness in the range of about 8 nm to about 12 nm.

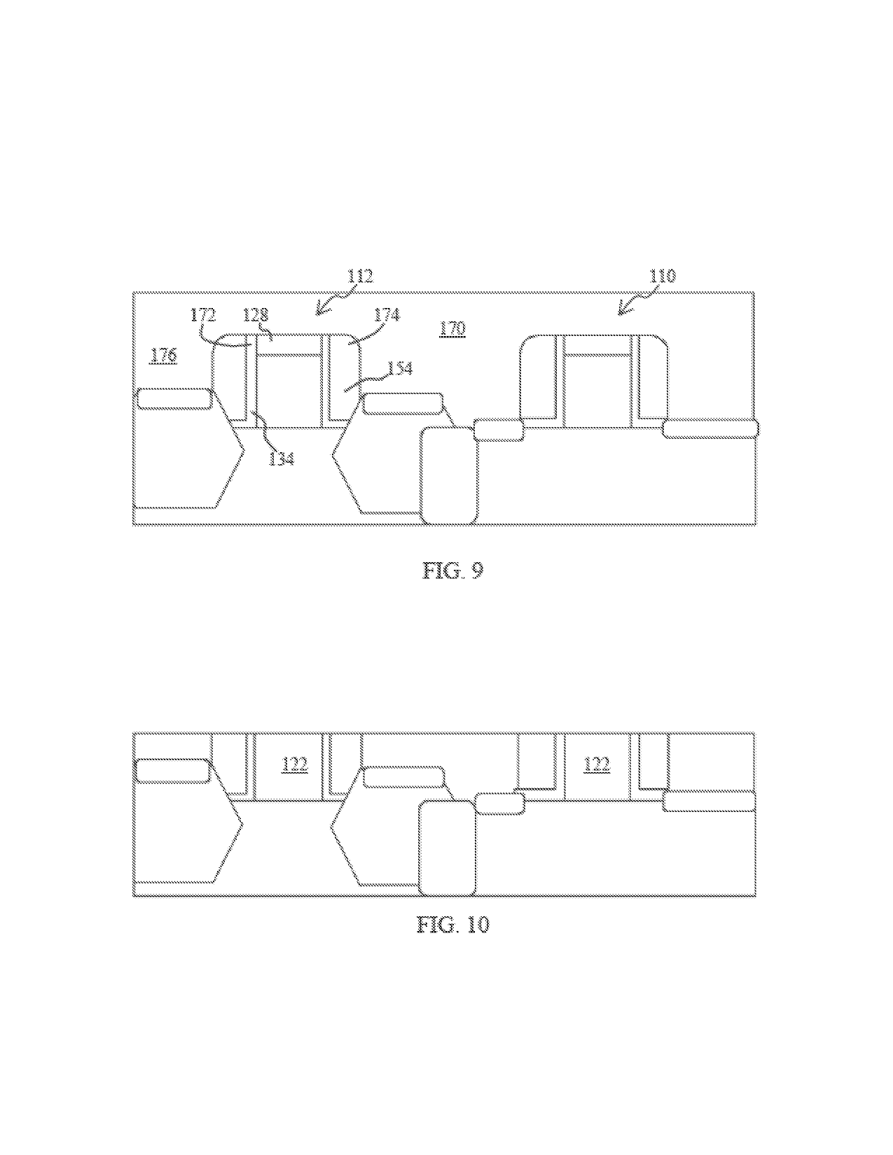

In accordance with a further embodiment herein, an insulating layer 170 is deposited over the gate structures 110, 112 as shown in FIG. 9. In the exemplary embodiment, the layer 170 is silicon oxide deposited by chemical vapor deposition (CVD) using tetraethylorthosilicate (TEOS). Cross-referencing FIGS. 9 and 10, it may be seen that the remaining cap layer 128, the portion 172 of the liner 134 abutting the remaining cap layer 128, the adjacent upper portion 174 of the spacer 154, and the upper portion 176 of the insulating layer 170 are removed to achieve the structure illustrated in FIG. 10. Specifically, this removal process may be performed by chemical-mechanical planarization. As shown, the removal process results in exposing the gate electrode material 122.

Referring now to FIG. 11, it may be seen that the illustrated structure is achieved by removing the gate electrode material 122. In an exemplary embodiment in which the electrode material 122 is polysilicon, an etch process using nitric acid (HNO₃), for example, removes the gate electrode material 122. As a result, the process exposes semiconductor substrate material 178 where the gate structures 110, 112 were formed. While not shown in the figures, a thin oxide layer (a dummy gate oxide) is initially grown underneath the polysilicon electrode material 122 as is well known. This oxide layer acts as an etch stop for the polysilicon etch.

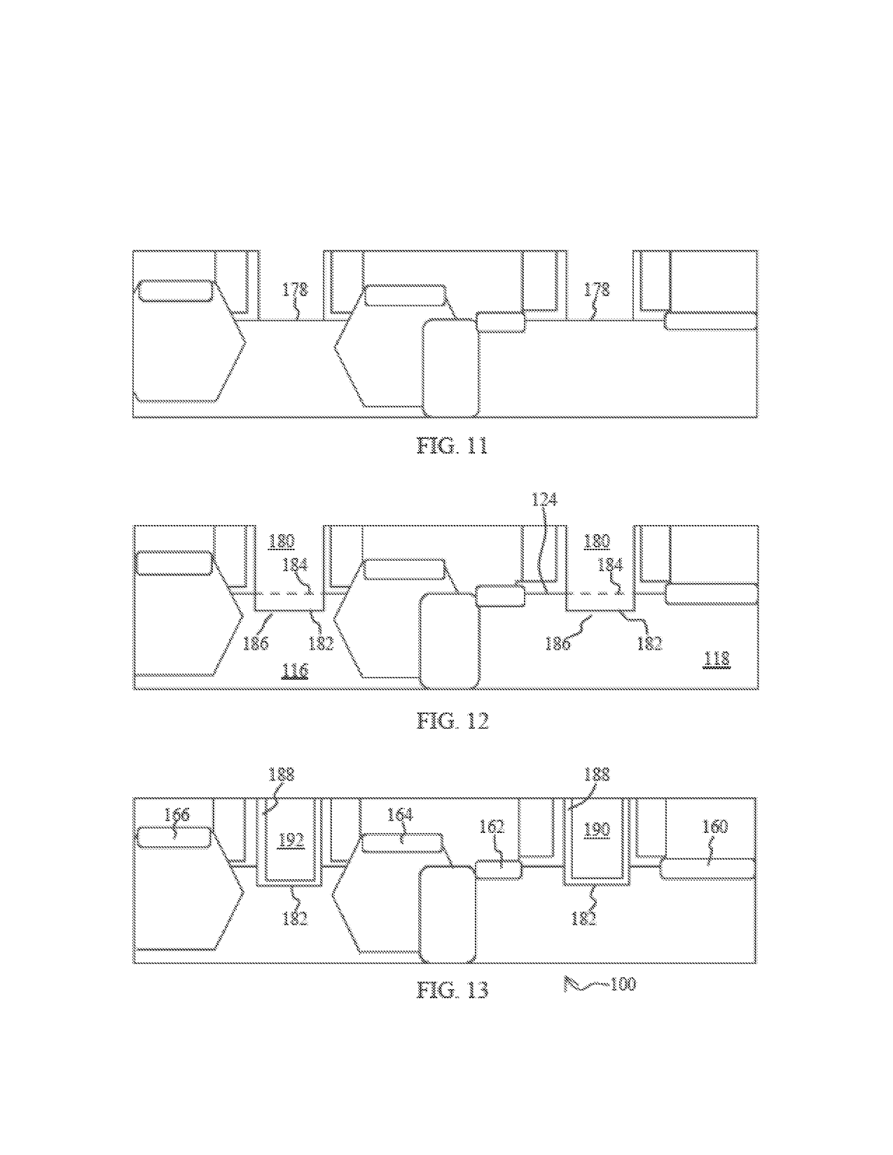

In FIG. 12, the fabrication method continues in the illustrated embodiment with the removal of a portion of the semiconductor substrate 118 to form recesses 180 with recessed gate surfaces 182. In the exemplary embodiment, the semiconductor substrate 118 is anisotropically etched, for example, through a process such as reactive ion etching including chlorine. Each recessed gate surface 182 is preferably about 10 to about 20 nm below the plane 184 defined by the surface 124 of the semiconductor substrate 118. As a result, the recessed gate surface 182 in isolated region 116 is in or is adjacent the narrow region 150 and is coincident with or is slightly above the line 146 defined as the shortest path between the sigma-shaped recesses 142. Further, the recessed gate surface 182 in isolated region 116 defines a channel region 186 that is in the narrow region 150 below the surface 182.

In accordance with a further embodiment herein, a high-K dielectric material 188 is deposited in the recesses 180 abutting the recessed gate surface 182 and the oxide liner 134. Further, metal-gate materials 190, 192 are deposited to fill the recesses 180. Thereafter, fabrication of the semiconductor device structure 100 may continue by forming contacts from silicide regions 160, 162, 164, 166. In an exemplary embodiment, the contact regions 160, 162, 164, 166 are formed by annealing, for example, by performing a rapid thermal anneal (RTA) for about sixty second at 260° C. to cause the silicide-forming metal to react with exposed silicon and form the metal silicide contact regions 160, 162, 164, 166 at the top of each of the source and drain regions. After forming the silicide contact regions 160, 162, 164, 166, fabrication of the semiconductor device structure 100 may be completed using well known final process steps (e.g., back end of line (BEOL) process steps), which will not be described in detail herein.

To briefly summarize, the fabrication methods described herein result in a lowered channel 186 beneath the gate structures 110, 112 to increase stress across the channel 186. Specifically, the channel 186 in isolated region 116 is lowered into the narrow region 150 around the closest path 146 between the sigma-shaped recesses 142 filled with stress-inducing material 152. As a result, the maximum stresses imposed by the material 152 are imposed in the channel 186 in the isolated region 116. Thus, the increased stress in the channel 186 results in enhanced carrier mobility and drive currents.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method for fabricating a transistor within and on a surface of a semiconductor substrate comprising:
forming a gate structure with a dummy gate electrode material overlying the semiconductor substrate;
etching recesses into the semiconductor substrate adjacent the gate structure and defining a narrow region between the recesses at a selected depth under the surface;
filling the recesses with a stress-inducing material;
removing the dummy gate electrode material to expose the semiconductor substrate; and
etching the exposed semiconductor substrate to form a recessed gate surface and defining a channel under the recessed gate surface in the narrow region.

2. The method of claim 1 wherein etching the recesses comprises etching sigma-shaped recesses, wherein each sigma-shaped recess forms an inward-facing point, and wherein the narrow region is defined between the inward-facing points of the recesses at the selected depth.

3. The method of claim 1 wherein etching the recesses comprises etching sigma-shaped recesses, wherein each sigma-shaped recess forms an inward-facing point, wherein the narrow region is defined between the inward-facing points of the recesses at the selected depth, and wherein the selected depth is about 10 to about 20 nm.

4. The method of claim 1 further comprising depositing high-k dielectric material onto the recessed gate surface.

5. The method of claim 4 further comprising depositing gate electrode metal onto the high-k material

6. The method of claim 1 wherein filling the recesses with the stress-inducing material comprises epitaxially growing SiGe in the recesses.

7. The method of claim 1 wherein forming the gate structure comprises depositing a cap overlying the dummy gate electrode material, the method further comprising:
depositing a liner over the gate structure, wherein an upper portion of the liner abuts the cap; and
removing the cap and the upper portion of the liner to expose the dummy gate electrode material.

8. The method of claim 7 wherein removing the cap and the upper portion of the liner comprises chemical-mechanical planarizing the gate structure.

9. The method of claim 1 wherein filling the recesses with the stress-inducing material comprises applying a maximum stress in the narrow region between the recesses.

10. The method of claim 1 wherein etching the exposed semiconductor substrate to form the recessed gate surface comprises anisotropically etching the semiconductor substrate to a depth of about 10 to about 20 nm.

11. A method for fabricating a transistor within and on a surface of a semiconductor substrate comprising:
etching recesses into the semiconductor substrate and defining a narrow region between the recesses at a selected depth under the surface;
filling the recesses with a stress-inducing material;
etching the semiconductor substrate between the recesses to form a recessed gate surface; and
forming a gate structure on the recessed surface and defining a gate channel under the recessed surface and in the narrow region.

12. The method of claim 11 wherein etching the recesses comprises etching sigma-shaped recesses, wherein each sigma-shaped recess forms an inward-facing point, and wherein the narrow region is defined between the inward-facing points of the recesses at the selected depth.

13. The method of claim 11 wherein etching the recesses comprises etching sigma-shaped recesses, wherein each sigma-shaped recess forms an inward-facing point, wherein the narrow region is defined between the inward-facing points of the recesses at the selected depth, and wherein the selected depth is about 10 to about 20 nm.

14. The method of claim 11 wherein filling the recesses with the stress-inducing material comprises epitaxially growing SiGe in the recesses.

15. The method of claim 11 wherein filling the recesses with the stress-inducing material comprises applying a maximum stress in the narrow region between the recesses.

16. The method of claim 11 wherein etching the semiconductor substrate between the recesses to form the recessed gate surface comprises anisotropically back etching the semiconductor substrate to a depth of about 10 to about 20 nm.

17. The method of claim 11 wherein forming the gate structure comprises depositing a dummy gate electrode material overlying the semiconductor substrate and depositing a cap overlying the dummy gate electrode material.

18. The method of claim 17 further comprising:
depositing a liner over the gate structure, wherein an upper portion of the liner abuts the cap;
removing the cap and the upper portion of the liner to expose the dummy gate electrode material; and
removing the dummy gate electrode to expose the semiconductor substrate between the recesses.

19. The method of claim 18 wherein removing the cap and the upper portion of the liner comprises chemical-mechanical planarizing the gate structure.

20. A transistor comprising:
a semiconductor substrate having a surface defining a plane;
stress-inducing regions embedded in the semiconductor substrate and defining a narrow region between the recesses at a selected depth under the surface;
a recessed gate surface formed below the plane;
a gate electrode formed on the recessed gate surface and defining a channel region at the selected depth and in the narrow region.
